(19) United States
(12) Patent Application Publication
(10) Pub. No.: US 2026/0059658 A1
(43) Pub. Date: Feb. 26, 2026

(54) PACKAGE SUBSTRATE AND FABRICATING METHOD THEREOF

(71) Applicant: AaltoSemi Inc., Jiangsu (CN)

(72) Inventors: Andrew C. CHANG, Jiangsu (CN); Min-Yao CHEN, Jiangsu (CN); Yin-Ju CHEN, Jiangsu (CN)

(21) Appl. No.: 19/306,372

(22) Filed: Aug. 21, 2025

(30) Foreign Application Priority Data
Aug. 21, 2024 (CN) 202411148612.5

(51) Int. Cl. H05K 1/03; H01L 23/498; H05K 1/11; H05K 3/28; H05K 3/40; H05K 3/42

(52) U.S. Cl. CPC H05K 1/036; H01L 23/49827; H05K 1/115; H05K 3/285; H05K 3/4015; H05K 3/42; H05K 2201/0154; H05K 2201/0166; H05K 2201/0175; H05K 2201/09563

(57) ABSTRACT

Provided are a package substrate and a method for fabricating the package substrate. The method is to form a wiring structure on a circuit structure having a core layer. The circuit structure is served as a ball-attach side to reduce the number of layers of the package substrate. Accordingly, the overall thickness of the package substrate is advantageously reduced.

### BACKGROUND

### 1. Technical Field

The present disclosure relates to a semiconductor packaging technology, and more particularly, to a package substrate capable of meeting thinning requirements and a fabricating method thereof.

### 2. Description of Related Art

With the booming development of the electronics industry, electronic products have trended toward being thinner, lighter, shorter, and smaller in form, and toward high performance, high functionality, and high speed in function. Hence, in order to meet the requirements for high integration density and miniaturization of semiconductor devices, package substrates designed for thinning, low warpage, and high-density wiring are often used in the packaging processes.

However, in conventional methods for fabricating package substrates, existing equipment poses a risk of damage under board thickness conditions, thus limiting its ability to process thinner substrates. Accordingly, producing package substrates that meet thinning and low-warpage design requirements requires installing specialized equipment having special specifications, making production costs difficult to reduce.

In addition, conventional methods for fabricating package substrates having a core layer generally adopt symmetric processes, forming an equal number of circuit layers on two opposite surfaces of the core layer. However, the ball-attach side of the package substrate (for connecting to a lower circuit board) and the die-attach side (for placing electronic elements) have different line widths. For example, the ball-attach side has larger electrical contact pads, while the die-attach side's die pads are relatively smaller, thus increasing process difficulty due to inconsistent layer counts and line widths on the top and bottom of the package substrate.

Therefore, how to overcome the various problems of the above-mentioned prior art has become an urgent issue to be solved.

### SUMMARY

In view of the various shortcomings of the prior art, the present disclosure provides a package substrate, which comprises: a circuit structure including a core layer and a circuit layer formed on each of two opposite surfaces of the core layer, wherein the core layer has conductive pillars electrically connected to the circuit layers, one side of the circuit structure is served as a ball-attach side, the other side of the circuit structure is served as a build-up side, and the circuit layer on the ball-attach side has a plurality of electrical contact pads; and a wiring structure disposed on the build-up side of the circuit structure and electrically connected to the circuit layer on the build-up side of the circuit structure.

The present disclosure further provides a method of fabricating a package substrate, and the method comprises: providing a plurality of circuit structures, wherein each of the plurality of circuit structures includes a core layer and a circuit layer formed on each of two opposite surfaces of the core layer, the core layer has conductive pillars electrically connected to the circuit layers, one side of each of the plurality of circuit structures is served as a ball-attach side, the other side of each of the plurality of circuit structures is served as a build-up side, and the circuit layer on the ball-attach side has a plurality of electrical contact pads; bonding the ball-attach side of each of the plurality of circuit structures to two opposite sides of a carrier; forming a wiring structure on the build-up side of each of the plurality of circuit structures, wherein the wiring structure is electrically connected to the circuit layer on the build-up side of each of the plurality of circuit structures; and removing the carrier.

In an embodiment of the aforementioned package substrate, the core layer of the circuit structure has a plurality of through-holes connecting the two opposite surfaces of the core layer, the circuit structure further has a bonding layer formed on the two opposite surfaces of the core layer and on wall surfaces of the plurality of through-holes and an insulating layer formed on the bonding layer, a plurality of vias corresponding to the plurality of through-holes are formed in the insulating layer, each of the conductive pillars is formed in each of the plurality of vias, and the circuit layer is formed on the insulating layer on each of the two opposite surfaces of the core layer and is electrically connected to the conductive pillars.

The present disclosure also provides a package substrate, which comprises: a circuit structure including: a core layer having a plurality of through-holes connecting two opposite surfaces of the core layer; a bonding layer formed on the two opposite surfaces of the core layer and on wall surfaces of the plurality of through-holes; an insulating layer formed on the bonding layer and having a plurality of vias corresponding to the plurality of through-holes; conductive pillars formed in the plurality of vias, respectively; and a circuit layer formed on the insulating layer on each of the two opposite surfaces of the core layer and electrically connected to the conductive pillars, wherein one side of the circuit structure is served as a ball-attach side, the other side of the circuit structure is served as a build-up side, and the circuit layer on the ball-attach side has a plurality of electrical contact pads; and a wiring structure disposed on the build-up side of the circuit structure and electrically connected to the circuit layer on the build-up side of the circuit structure, wherein an outermost side of the wiring structure has a plurality of electrical contact pads, and a width of each of the plurality of electrical contact pads on the outermost side of the wiring structure is less than a width of each of the plurality of electrical contact pads of the circuit layer.

In an embodiment of the aforementioned package substrate and method, the bonding layer is an organic coating or an inorganic coating.

In an embodiment of the aforementioned package substrate and method, the organic coating is made of a polymer.

In an embodiment of the aforementioned package substrate and method, the polymer is selected from at least one member of a group consisting of polyphenylene oxide, polyamide, and poly-dimethylbenzene.

In an embodiment of the aforementioned package substrate and method, the organic coating has a thickness of 1 nm to 100 μm.

In an embodiment of the aforementioned package substrate and method, the inorganic coating comprises silica sand having a diameter of 20 μm to 50 μm and a roughness Ra of 1 μm to 200 μm.

In an embodiment of the aforementioned package substrate and method, the insulating layer comprises a dielectric material or an ink material.

In an embodiment of the aforementioned package substrate and method, the dielectric material is selected from at least one member of a group consisting of polybenzoxazole, polyimide, prepreg, and Ajinomoto Build-up Film, and the ink material comprises epoxy ink composites.

In an embodiment of the aforementioned package substrate and method, the ink material has a viscosity of 25 Pa·s to 55 Pa·s, a glass transition temperature of 145° C. to 180°C., and/or Young's modulus of 3 GPa to 10 GPa.

As can be seen from the above, in the package substrate and the fabricating method thereof of the present disclosure, by using the circuit structure having the core layer as the ball-attach side, the number of layers of the package substrate is reduced. Accordingly, the overall thickness of the package substrate is advantageously reduced as compared to the prior art.

In addition, regardless of any of the above-mentioned processes, the circuit structure having the through-holes can be fabricated into a BGA-specification package substrate.

Also, the core layer is designed to have high-hardness, so the warpage problem can be effectively prevented from occurring in the package substrate.

Further, the present disclosure can shorten the conductive path to reduce signal loss by using the circuit structure having the core layer as the ball-attach side, on which the solder balls are directly in contact with the circuit board.

### BRIEF DESCRIPTION OF THE DRAWINGS

FIG. 1A-1 to FIG. 1E are schematic cross-sectional views illustrating a fabricating method of a package substrate according to a first embodiment of the present disclosure, and FIG. 1A-2 shows that when a core layer is made of a glass material, an organic coating bonding layer penetrates cracks in the core layer made of the glass material.

FIG. 1F is a schematic cross-sectional view showing the subsequent process of FIG. 1E.

FIG. 2A to FIG. 2C are schematic cross-sectional views illustrating a fabricating method of a package substrate according to a second embodiment of the present disclosure.

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “in,” “inside,” “out,” “outside,” “a,” “an,” “one,” and the like are merely for clear explanation rather than limiting the practicable scope of the present disclosure, and thus, alterations or adjustments of the relative relationships thereof without essentially altering the technical content should still be considered in the practicable scope of the present disclosure.

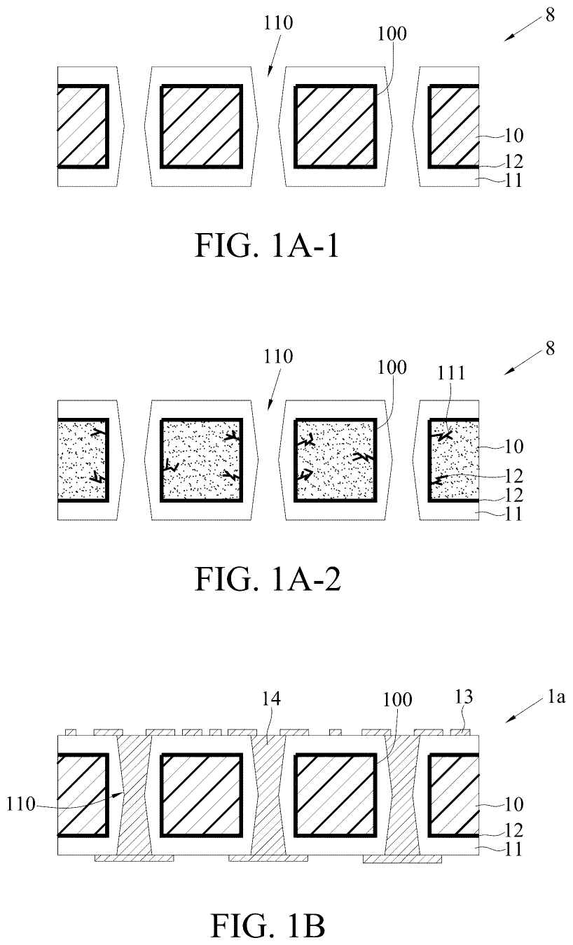

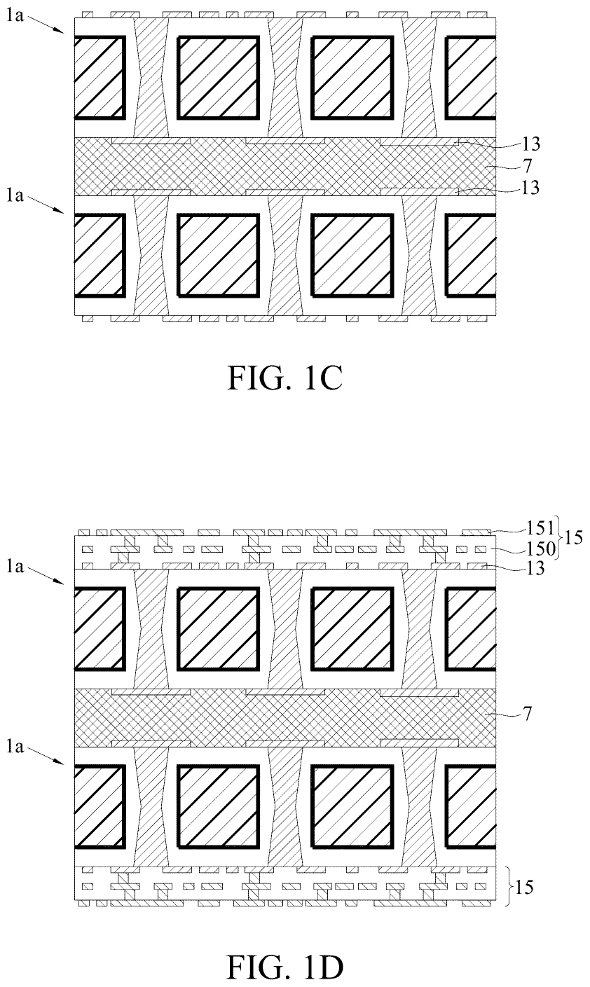

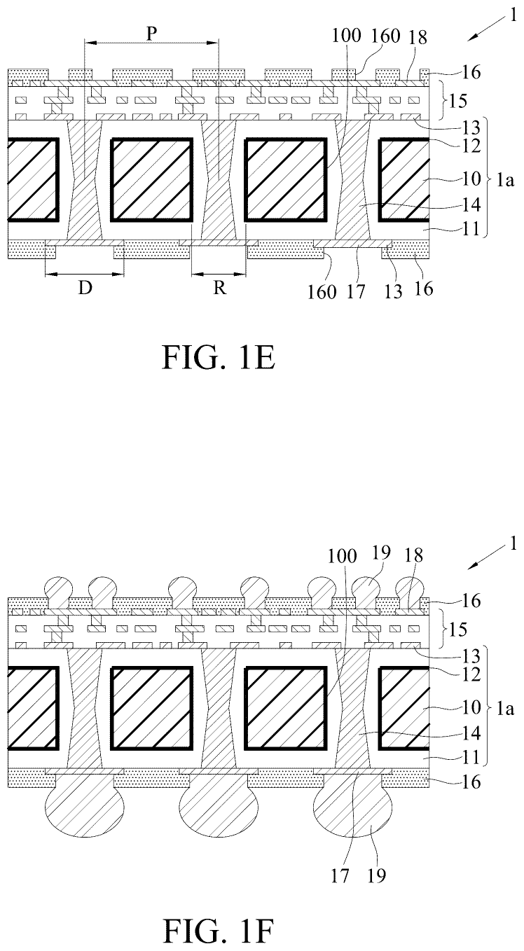

FIG. 1A-1 to FIG. 1E are schematic cross-sectional views illustrating a fabricating method of a package substrate 1 according to the present disclosure.

As shown in FIG. 1A-1, a substrate 8 is provided. The substrate 8 includes a core layer 10 having a plurality of through-holes 100 and an insulating layer 11 formed on the core layer 10 and in the through-holes 100. A plurality of vias 110 respectively corresponding to the through-holes 100 are formed in the insulating layer 11.

In an embodiment, the core layer 10 is made of a high-hardness dielectric material, such as glass, ceramic, SiC, AlO₂, or a composite material. In order to improve adhesion on the surfaces of the core layer 10 and the wall surfaces of the through-holes 100, a bonding layer 12 is first formed on the two opposite surfaces of the core layer 10 and the wall surfaces of the through-holes 100, then the insulating layer 11 is bonded via the bonding layer 12.

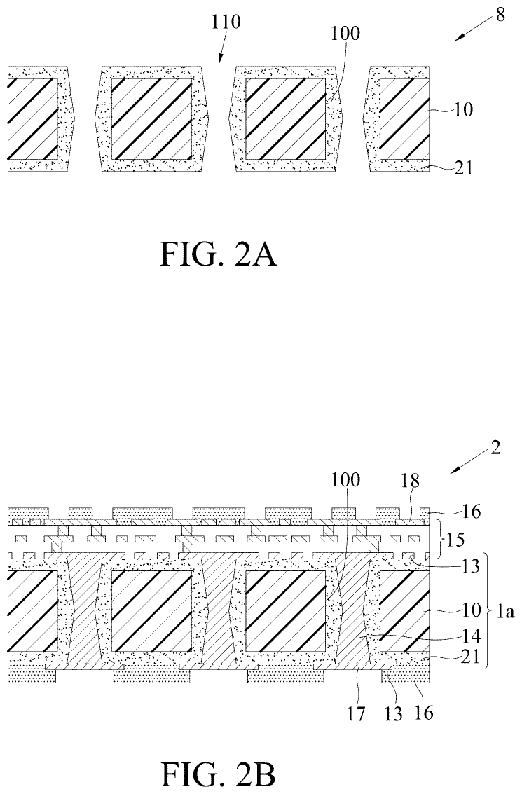

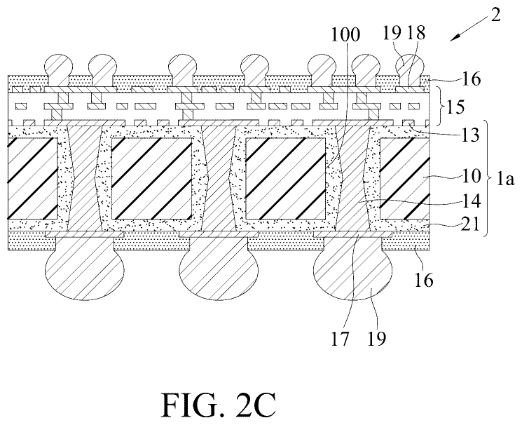

In addition, the bonding layer 12 may be an organic coating (organic coating layer) formed by chemical processes, e.g., depositing organic polymers such as polyphenylene oxide (PPO), polyamide, or poly-dimethylbenzene (PD). Moreover, a thinner organic coating may be formed by chemical vapor deposition (CVD) to improve isolation, corrosion resistance, and protect the surfaces of the high-rigidity core layer 10, with a thickness of, for example, 1 nm to 100 μm. The organic coating may penetrate cracks to limit crack propagation; as shown in FIG. 1A-2, the organic coating bonding layer 12 penetrates cracks 111 in the core layer 10 made of glass material, reducing the dielectric constant (Dk) of the core layer 10 to 2.5 to 5 at 1 GHz (such as 2.5, 2.65, 2.7, 2.8, 2.9, 3.0, 3.2, 3.5, 3.7, 4.0, 4.2, 4.5, 4.7, and 5.0 at 1 GHz).

On the other hand, the bonding layer 12 may also be an inorganic coating (inorganic coating layer) formed by physical processes to generate van der Waals forces. For example, sandblasting with silica sand (20 μm to 50 μm diameter, 1 μm to 200 μm roughness Ra) can remove oxides and impurities on the core layer 10 and increase the surface area of the core layer 10, thereby improving adhesion of the insulating layer 11 on the core layer 10 made of high-hardness material. Thus, in an embodiment, the bonding layer 12 is formed by silica sand having a diameter of 20 μm to 50 μm and a roughness Ra of 1 μm to 200 μm.

Further, the insulating layer 11 is made of a dielectric material, such as polybenzoxazole (PBO), polyimide (PI), prepreg (PP), Ajinomoto Build-up Film (ABF), or other dielectric materials.

Alternatively, the insulating layer 21 is made of an ink material that can be formed by filling methods such as injection, plugging, or coating, as shown in FIG. 2A. For example, the ink material primarily includes epoxy ink composites, which have physical properties such as viscosity of 25 Pa·s to 55 Pa·s, glass transition temperature (Tg) of 145° C. to 180° C., and/or Young's modulus of 3 GPa to 10 GPa, etc. Hence, the bonding layer 12 may be selectively fabricated or not fabricated, and the insulating layer 21 is directly bonded to the core layer 10. Therefore, by filling the through-holes 100 of the core layer 10 with injecting ink (plugging ink), the cost of process and material consumption can be reduced.

In addition, each of the through-holes 100 is in a straight cylinder shape, and each of the vias 110 is in a biconical hole shape such as an hourglass shape (hourglass-shaped double cones). For example, the plurality of through-holes 100 and the plurality of vias 110 are formed by laser drilling. In addition, the insulating layer 11 is formed on the bonding layer 12 to cover the core layer 10, such that the depth of each of the vias 110 is greater than the depth of each of the through-holes 100.

As shown in FIG. 1B, conductive pillars 14 are formed by plating in the vias 110. Patterned wiring processes are performed on the insulating layer 11 on two opposite surfaces of the substrate 8, so that a circuit layer 13 is formed on the insulating layer 11 on each of two opposite surfaces of the core layer 10, and at least one conductive pillar 14 electrically connected to the circuit layers 13 is formed in each via 110, thereby forming a circuit structure 1a.

In an embodiment, one side of the circuit structure 1a (or the core layer 10) is defined as the ball-attach side, and the other side of the circuit structure 1a (or the core layer 10) is defined as the build-up side.

As shown in FIG. 1C, the circuit structure 1a is bonded to each of two opposite sides of a carrier 7. Each of the circuit structures 1a is bonded to the carrier 7 via the ball-attach side thereof.

In an embodiment, the carrier 7 is made of a double-capacity adhesive material, such as a double-sided adhesive thermal release film. The circuit structures 1a are pressed onto both sides of the carrier 7, such that the circuit layer 13 on one of the sides (the ball-attach side) of each of the circuit structures 1a is embedded in the carrier 7.

As shown in FIG. 1D, a wiring structure 15 electrically connected to the circuit layer 13 is formed on the other side (the build-up side) of each of the circuit structures 1a.

In an embodiment, the wiring structure 15 includes at least one dielectric layer 150 disposed on the insulating layer 11 and at least one wiring layer 151 formed on the dielectric layer 150 and electrically connected to the circuit layer 13, such as the two-layer wiring layer 151 shown in FIG. 1D. For example, the wiring structure 15 is fabricated by electroplating metal (e.g., copper) or other methods by means of using a build-up process.

Furthermore, the dielectric layer 150 may be made of Ajinomoto Build-up Film (ABF) or other dielectric materials, and the wiring layer 151 is made of copper, following redistribution layer (RDL) specifications. For example, the wiring structure 15 may have three wiring layers 151 with line width/line spacing (L/S) from the exposed side toward the core layer 10 sequentially 5/5 μm, 8/10 μm, and 15/15 μm.

As shown in FIG. 1E, the carrier 7 is removed to expose the circuit layer 13. Subsequently, solder-resist layers 16 are formed on the outermost side of the wiring structure 15 and on the circuit layer 13, respectively, and the circuit layer 13 on the ball-attach side and the outermost wiring layer 151 are exposed from the solder-resist layers 16 to serve as electrical contact pads 17, 18, thus forming a plurality of package substrates 1. In addition, as shown in FIG. 1E, the outermost side of the wiring structure 15 has the plurality of electrical contact pads 18, and the width of each of the plurality of electrical contact pads 18 on the outermost side of the wiring structure 15 is less than the width of each of the plurality of electrical contact pads 17 of the circuit layer 13.

In an embodiment, the solder-resist layers 16 are formed with a plurality of openings 160 that expose the outermost wiring layer 151 and the circuit layer 13 on the ball-attach side, such that the electrical contact pads 17 of the circuit layer 13 can be used as ball-attach pads (the width D of each of the electrical contact pads 17 is greater than the width of each of the electrical contact pads 18 of the wiring structure 15), and such that the package substrate 1 forms a ball grid array (BGA) package. For example, the specifications of the circuit structure 1a, such as the width (e.g., diameter) D of the electrical contact pad 17, the spacing P between the conductive pillars 14, and the diameter R of the through-hole 100, are designed to meet the requirements of the BGA package. That is, the side of the circuit structure 1a with the ball-attach pads is only configured with the circuit layer 13 (or the electrical contact pads 17), with no wiring fabricated above.

Further, if the process shown in FIG. 2A is continued, another embodiment—a package substrate 2—is obtained as shown in FIG. 2B.

Also, in subsequent fabricating processes, as shown in FIG. 1F or FIG. 2C, a plurality of solder balls 19 electrically connecting the outermost wiring layer 151 and the circuit layer 13 on the ball-attach side can be bonded to the electrical contact pads 17, 18, allowing the package substrate 1, 2 to be connected to electronic devices (not shown) such as semiconductor chips, passive components, silicon interposers, circuit boards, or other components via the solder balls 19.

Therefore, in the package substrate 1, 2 and the fabricating method thereof of the present disclosure, by using the circuit structure 1a having the core layer 10 as the ball-attach side, the number of layers of the package substrate 1, 2 is reduced. Accordingly, the overall thickness of the package substrate 1, 2 is advantageously reduced as compared to the prior art.

In addition, regardless of any of the above-mentioned processes, the substrate 8 having the through-holes 100 can be fabricated into a BGA-specification package substrate 1, 2.

Also, the core layer 10 is designed to have high-hardness, so the warpage problem can be effectively prevented from occurring in the package substrate 1, 2.

Further, by using the circuit structure 1a having the core layer 10 as the ball-attach side, on which the solder balls 19 are directly in contact with the circuit board, the conductive path is shortened, thereby reducing signal loss.

The present disclosure also provides a package substrate 1, 2. The package substrate 1, 2 comprises a circuit structure 1a and a wiring structure 15.

The circuit structure 1a includes a core layer 10 and a circuit layer 13 formed on each of two opposite surfaces of the core layer 10, and the core layer 10 has conductive pillars 14 electrically connected to the circuit layers 13. One side of the circuit structure 1a is served as a ball-attach side, and the other side of the circuit structure 1a is served as a build-up side. The circuit layer 13 on the ball-attach side has a plurality of electrical contact pads 17.

The wiring structure 15 is disposed on the build-up side of the circuit structure 1a and is electrically connected to the circuit layer 13 on the build-up side of the circuit structure 1a.

More specifically, the package substrate 1, 2 of the present disclosure comprises: a circuit structure 1a including: a core layer 10 having a plurality of through-holes 100 connecting two opposite surfaces of the core layer 10; a bonding layer 12 formed on the two opposite surfaces of the core layer 10 and on wall surfaces of the through-holes 100; an insulating layer 11, 21 formed on the bonding layer 12 and having a plurality of vias 110 corresponding to the through-holes 100; conductive pillars 14 formed in the vias 110, respectively; and a circuit layer 13 formed on the insulating layer 11, 21 on each of the two opposite surfaces of the core layer 10 and electrically connected to the conductive pillars 14, wherein one side of the circuit structure 1a is served as a ball-attach side, and the other side of the circuit structure 1a is served as a build-up side, and the circuit layer 13 on the ball-attach side has a plurality of electrical contact pads 17; and a wiring structure 15 disposed on the build-up side of the circuit structure 1a and electrically connected to the circuit layer 13 on the build-up side of the circuit structure 1a.

In summary, in the package substrate and the fabricating method thereof of the present disclosure, by using the circuit structure having the core layer as the ball-attach side, the number of layers of the package substrate is reduced. Accordingly, the overall thickness of the package substrate is advantageously reduced.

In addition, regardless of any of the above-mentioned processes, the substrate having the through-holes can be fabricated into a BGA-specification package substrate.

Also, the core layer is designed to have high-hardness, so the warpage problem can be effectively prevented from occurring in the package substrate.

Further, the present disclosure can shorten the conductive path to reduce signal loss by using the circuit structure having the core layer as the ball-attach side, on which the solder balls are directly in contact with the circuit board.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a circuit structure including a core layer and a circuit layer formed on each of two opposite surfaces of the core layer, wherein the core layer has conductive pillars electrically connected to the circuit layers, one side of the circuit structure is served as a ball-attach side, the other side of the circuit structure is served as a build-up side, and the circuit layer on the ball-attach side has a plurality of electrical contact pads; and
a wiring structure disposed on the build-up side of the circuit structure and electrically connected to the circuit layer on the build-up side of the circuit structure.

2. The package substrate of claim 1, wherein the core layer of the circuit structure has a plurality of through-holes connecting the two opposite surfaces of the core layer, the circuit structure further has a bonding layer formed on the two opposite surfaces of the core layer and on wall surfaces of the plurality of through-holes and an insulating layer formed on the bonding layer, a plurality of vias corresponding to the plurality of through-holes are formed in the insulating layer, each of the conductive pillars is formed in each of the plurality of vias, and the circuit layer is formed on the insulating layer on each of the two opposite surfaces of the core layer and is electrically connected to the conductive pillars.

3. The package substrate of claim 2, wherein the bonding layer is an organic coating or an inorganic coating.

4. The package substrate of claim 3, wherein the organic coating is made of a polymer.

5. The package substrate of claim 4, wherein the polymer is selected from at least one member of a group consisting of polyphenylene oxide, polyamide, and poly-dimethylbenzene.

6. The package substrate of claim 3, wherein the organic coating has a thickness of 1 nm to 100 μm.

7. The package substrate of claim 3, wherein the inorganic coating comprises silica sand having a diameter of 20 μm to 50 μm and a roughness Ra of 1 μm to 200 μm.

8. The package substrate of claim 2, wherein the insulating layer comprises a dielectric material or an ink material.

9. The package substrate of claim 8, wherein the dielectric material is selected from at least one member of a group consisting of polybenzoxazole, polyimide, prepreg, and Ajinomoto Build-up Film, and the ink material comprises epoxy ink composites.

10. The package substrate of claim 9, wherein the ink material has a viscosity of 25 Pa·s to 55 Pa·s and a glass transition temperature of 145° C. to 180° C.

11. A method of fabricating a package substrate, comprising:
providing a plurality of circuit structures, wherein each of the plurality of circuit structures includes a core layer and a circuit layer formed on each of two opposite surfaces of the core layer, the core layer has conductive pillars electrically connected to the circuit layers, one side of each of the plurality of circuit structures is served as a ball-attach side, the other side of each of the plurality of circuit structures is served as a build-up side, and the circuit layer on the ball-attach side has a plurality of electrical contact pads;
bonding the ball-attach side of each of the plurality of circuit structures to two opposite sides of a carrier;
forming a wiring structure on the build-up side of each of the plurality of circuit structures, wherein the wiring structure is electrically connected to the circuit layer on the build-up side of each of the plurality of circuit structures; and
removing the carrier.

12. The method of claim 11, wherein steps for forming each of the plurality of circuit structures comprise:
providing the core layer with a plurality of through-holes connecting the two opposite surfaces of the core layer;
forming a bonding layer on the two opposite surfaces of the core layer and on wall surfaces of the plurality of through-holes;
forming an insulating layer on the bonding layer;
forming a plurality of vias corresponding to the plurality of through-holes in the insulating layer;
forming the conductive pillars in the plurality of vias, respectively; and
forming the circuit layer on the insulating layer on each of the two opposite surfaces of the core layer, wherein the circuit layers are electrically connected to the conductive pillars.

13. The method of claim 12, wherein the bonding layer is an organic coating or an inorganic coating.

14. The method of claim 13, wherein the organic coating is made of a polymer.

15. The method of claim 14, wherein the polymer is selected from at least one member of a group consisting of polyphenylene oxide, polyamide, and poly-dimethylbenzene.

16. The method of claim 13, wherein the organic coating has a thickness of 1 nm to 100 μm.

17. The method of claim 13, wherein the inorganic coating comprises silica sand having a diameter of 20 μm to 50 μm and a roughness Ra of 1 μm to 200 μm.

18. The method of claim 12, wherein the insulating layer comprises a dielectric material or an ink material.

19. The method of claim 18, wherein the dielectric material is selected from at least one member of a group consisting of polybenzoxazole, polyimide, prepreg, and Ajinomoto Build-up Film, and the ink material comprises epoxy ink composites.

20. The method of claim 18, wherein the ink material has a viscosity of 25 Pa·s to 55 Pa·s and a glass transition temperature of 145° C. to 180° C.

21. A package substrate, comprising:
a circuit structure including:
a core layer having a plurality of through-holes connecting two opposite surfaces of the core layer;
a bonding layer formed on the two opposite surfaces of the core layer and on wall surfaces of the plurality of through-holes;
an insulating layer formed on the bonding layer and having a plurality of vias corresponding to the plurality of through-holes;
conductive pillars formed in the plurality of vias, respectively; and
a circuit layer formed on the insulating layer on each of the two opposite surfaces of the core layer and electrically connected to the conductive pillars, wherein one side of the circuit structure is served as a ball-attach side, the other side of the circuit structure is served as a build-up side, and the circuit layer on the ball-attach side has a plurality of electrical contact pads; and
a wiring structure disposed on the build-up side of the circuit structure and electrically connected to the circuit layer on the build-up side of the circuit structure, wherein an outermost side of the wiring structure has a plurality of electrical contact pads, and a width of each of the plurality of electrical contact pads on the outermost side of the wiring structure is less than a width of each of the plurality of electrical contact pads of the circuit layer.

22. The package substrate of claim 21, wherein the bonding layer is an organic coating or an inorganic coating.

23. The package substrate of claim 22, wherein the organic coating is made of a polymer.

24. The package substrate of claim 23, wherein the polymer is selected from at least one member of a group consisting of polyphenylene oxide, polyamide, and poly-dimethylbenzene.

25. The package substrate of claim 22, wherein the organic coating has a thickness of 1 nm to 100 μm.

26. The package substrate of claim 22, wherein the inorganic coating comprises silica sand having a diameter of 20 μm to 50 μm and a roughness Ra of 1 μm to 200 μm.
